(19) United States
(12) Patent Application Publication
(10) Pub. No.: US 2010/0212702 A1
(43) Pub. Date: Aug. 26, 2010

(54) Cleaning Member, Substrate Cleaning Apparatus and Substrate Processing Apparatus

(76) Inventor: Satomi Hamada, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 11/922,093

(22) PCT Filed: Sep. 7, 2006
(86) PCT No.: PCT/JP2006/318212

§ 371 Date: Dec. 13, 2007

(30) Foreign Application Priority Data
Sep. 15, 2005 (JP) 2005-268740

(51) Int. Cl. B08B 3/00

(52) U.S. Cl. 134/115 R

(57) ABSTRACT

An object of the present invention is to provide a cleaning member, a substrate cleaning apparatus and a substrate processing apparatus, which are adapted to work with a reduced amount of contaminants to be discharged from the cleaning member, to prevent inverse contamination in a substrate subject to the cleaning and to preserve a high cleaning power to the substrate in a stable manner. The object is accomplished by a cleaning member of a substrate cleaning apparatus for cleaning a surface of a substrate subject to the cleaning by using a relative motion between the surface of the substrate subject to the cleaning and the cleaning member brought into contact with the surface of the substrate, while supplying a cleaning liquid onto the surface of the substrate, the cleaning member comprising a core portion (23a) made of a waterproof material, wherein a surface of the core portion (23a) is covered with a porous polymeric material to define a coating layer (23b). The porous polymeric material to be used may be selected form a group consisting of PVA polymers, acrylic acid polymers, other addition polymers, acryl amide polymers, polyoxyethylene polymers, polyether polymers, condensation polymers, polyvinyl pyrrolidone, polystyrene aurfonic acid, urethane resins, and polyurethane resins.

### TECHNICAL FIELD

The present invention relates to a cleaning member used for cleaning a substrate, more particularly to a cleaning member adapted to work with a reduced amount of contaminants to be discharged from the cleaning member, to prevent inverse contamination of a substrate subject to the cleaning and to provide a high cleaning power to a substrate in a stable manner, and also relates to a substrate cleaning apparatus and a substrate processing apparatus, which are equipped with the same cleaning member.

### BACKGROUND OF THE INVENTION

One method has been commonly practiced for a physical cleaning process favorably owing to its higher effect on removing the contaminant and simplicity in its operation, in which a surface of a substrate subject to the cleaning is brought into contact with a cleaning member while supplying a cleaning liquid onto the surface such that the contaminant on a surface of a substrate subject to the cleaning can be removed by using a relative motion between the substrate and a cleaning member. The cleaning member used in this method has often employed a single material of absorbent polymer formed in a cylindrical or a circular disk configuration. Further, since the polymeric material is often porous having a pore size in a range of some μm to 300 μm, it is more apt to contain particles during its being formed. Although sufficient cleaning, if provided previously, can help reduce a number of particles contained in the polymeric material, the particles could not be completely removed, and it rather seems more difficult to remove the contained particles as a larger volume of cleaning member is used.

When the cleaning member implemented by such a cleaning member made of polymeric material is used to clean the substrate, owing to the high water absorbing property inherent to the polymeric material, the contaminant along with the cleaning liquid could enter into the cleaning member. Although the cleaning member can once trap the particles of contaminant in the pores, it may permit the particles to be discharged from the cleaning member, leading to the inverse contamination induced over the substrate. When cleaning a substrate coated with a metal film made of Cu and the like, typically the cleaning member used would be contaminated with the Cu to such a degree that can be visually recognized readily by the end of the cleaning process performed on a few pieces of substrates. Accordingly, in the current situation, the cleaning member is used to clean the substrate while letting the contamination spread unavoidably from the nature of water absorbing property thereof.

### LIST OF REFERENCE PATENT DOCUMENTS

### [Patent Document 1]

Japanese Patent Laid-open Publication No. H05-317783

### [Patent Document 2]

Japanese Patent Publication No. 2875213

### SUMMARY OF THE INVENTION

To solve the problem described above, a self-cleaning method for the cleaning member has also been suggested, in which the cleaning liquid may be sprayed over the cleaning member or the cleaning member may be cleaned in a liquid bath under irradiation of ultrasonic waves in a system equipped with an ultrasonic transducer, as disclosed in the above Patent Document 1, but in actual practice, it has been found to be difficult to keep the cleaning member always in a satisfactory level of cleanness, because the contamination has often spread into the cleaning member. In one approach to address those problems, a zeta(ζ) potential control by way of a chemical solution, such as a surfactant, and/or a gas dissolved solution has been applied in order to reduce the possibility for discharged contaminants to adhere inversely to the substrate to be cleaned. However, it is indeed unavoidable that the contamination could spread gradually deep into the cleaning member to increase an accumulation of contaminants, as the cleaning member is used continuously. In addition, any specific type of film used in the substrate may limit the type of cleaning liquid to be used, and in such circumstances as described above, there has been a need for a fundamental solution to the problems.

The present invention has been made in the light of the above viewpoints, and an object thereof is to provide a cleaning member, a substrate cleaning apparatus and a substrate processing apparatus, which are adapted to work with a reduced amount of contaminants to be discharged from the cleaning member, to prevent inverse contamination in a substrate subject to the cleaning, and to preserve a high cleaning power to the substrate in a stable manner.

To accomplish the above object, an invention as defined in claim 1 provides a cleaning member of a substrate cleaning apparatus for cleaning a surface of a substrate to be cleaned by using a relative motion between said surface of the substrate and the cleaning member brought into contact with the surface of the substrate, while supplying a cleaning liquid onto the surface of the substrate, the cleaning member comprising a waterproof core portion, wherein a surface of the core portion is coated with a porous polymeric material to define a coating layer.

An invention as defined in claim 2 provides a cleaning member in accordance with claim 1, in which the porous polymeric material is made of any one of polymeric materials selected from a group consisting of PVA (polyvinyl alcohol) polymers, acrylic acid polymers, other addition polymers, acryl amide polymers, polyoxyethylene polymers, polyether polymers, condensation polymers, polyvinyl pyrrolidone, polystyrene aurfonic acid, urethane resins, and polyurethane resins.

An invention as defined in claim 3 provides a cleaning member in accordance with claim 1, in which a thickness of the coating layer of a porous polymeric material is in a range of 5 μm to 15 mm.

An invention as defined in claim 4 provides a cleaning member in accordance with claim 1, in which the core portion is composed of any one of waterproof materials selected from a group consisting of: flexible cellular plastic foams; soft rubbers including fluoro rubber, silicon rubber, PHOSPHAZENE rubber and urethane rubber; and epoxy resins.

An invention as defined in claim 5 provides a cleaning member in accordance with claim 1, in which a hardness of the coating layer of the porous polymeric material in wet condition is equal to or lower than 100. It is to be noted that the hardness meter used herein is a durometer, Model No. GS-743G manufactured by Teclock.

An invention as defined in claim 6 provides a cleaning member in accordance with claim 1, in which a waterproof layer made of waterproof material is formed between the coating layers of the porous polymeric material or between the coating layer and the core portion.

An invention as defined in claim 7 provides a substrate cleaning apparatus for cleaning a surface of a substrate to be cleaned by using a relative motion between the surface of the substrate and a cleaning member brought into contact with the surface of the substrate, while supplying a cleaning liquid onto the surface of the substrate, the substrate cleaning apparatus employing a cleaning member in accordance with any one of claims 1 to 6 for implementing the cleaning member of the substrate cleaning apparatus.

An invention as defined in claim 8 provides a substrate cleaning apparatus in accordance with claim 7, comprising a hardness meter, a thin film hardness meter or a CCD for monitoring whether or not the coating layer of the porous polymeric material is present in the cleaning member.

An invention as defined in claim 9 provides a substrate cleaning apparatus in accordance with claim 8, further comprising a means for outputting a replacement signal when a pore distribution or hardness monitored on the cleaning member is shifted from a condition of the coating layer of the porous polymeric material to a condition of the core portion.

An invention as defined in claim 10 provides a substrate processing apparatus comprising a substrate processing section for carrying out a predetermined course of processing on a substrate and a substrate cleaning section for cleaning the substrate that has finished with the predetermined course of processing in the substrate processing section, the substrate processing apparatus employing a substrate cleaning apparatus in accordance with any one of claims 7 to 9 for implementing the substrate cleaning section of the substrate processing apparatus.

### EFFECT OF THE INVENTION

According to the inventions as defined in claims 1 and 2, since the cleaning member is provided with the coating layer comprising the porous polymeric material over the surface of the waterproof core portion, thereby forming the coating layer of a highly flexible water absorbing porous polymeric material in the region of the cleaning member to be brought into direct contact with the substrate, the present invention can achieve a cleaning member adapted to block any contaminants from entering the inside or the core portion of the cleaning member and thus to reduce the possibility of inverse contamination to be induced in the substrate, while an excellent cleaning power can be still maintained.

According to the invention as defined in claim 3, since the thickness of the coating layer of the porous polymeric material is specified to be in the range of 5 μm to 15 mm, the coating layer of the porous polymeric material can be made thin, meaning that the volume of the portion available for the contaminant to be accumulated can be reduced, which in turn helps to reduce the possibility of inverse contamination to be induced in the substrate.

According to the invention as defined in claim 4, since the core portion is composed of any one of a waterproof material selected from a group consisting of: flexible cellular plastic foams; soft rubbers including fluoro rubber, silicon rubber, phosphazene rubber and urethane rubber; and epoxy resins, and therefore, the core portion has waterproof property and resilience, the cleaning member can be protected from any contaminants which otherwise could enter into the core portion, thereby reducing the amount of the contaminants to be accumulated and thus the possibility of inverse contamination to be induced in the substrate, while a flexibility as well as an ability for removing the contaminants of the cleaning member being maintained as a whole, in spite of the thin coating layer of the porous polymeric material.

According to the invention as defined in claim 5, since the hardness of the coating layer of the porous polymeric material in a wet condition is specified to be equal or lower than 100 (as measured by using a durometer, Model No. GS-743G manufactured by Teclock as the hardness meter), the flexible property can be preserved in the coating layer made of porous polymeric material which comes into direct contact with the substrate, so that no damage would be caused to the substrate. In this regard, a hardness higher than 100 in the coating layer could possibly lead to the damaged substrate.

According to the invention as defined in claim 6, since the waterproof layer made of a waterproof material is formed between the coating layers of the porous polymeric material or between the coating layer and the core portion, it is allowed for the thickness of the coating layer defined in the outer side with respect to the layer of waterproof material to be made thinner without any fear that any contaminant-contained liquid or contaminants could enter (penetrate) into the inside region with respect to the layer of waterproof material, thereby reducing the volume of contaminant-contained liquid or contaminants to be accumulated in the cleaning member and thus reducing the possibility of inverse contamination to be induced in the substrate, while at the same time, the total thickness of the coating layer can be made thick enough to ensure the flexibility of the cleaning member as a whole. In addition, since there is no need to consider the waterproof property of the material to be selected for forming the core portion, a broad range of possibility is provided for selecting the material, as the material having excellent properties exclusively favorable for the core portion can be selected.

According to the invention as defined in claim 7, since the cleaning member of the substrate cleaning apparatus employs the substrate cleaning member in accordance with any one of claims 1 to 6, it becomes possible to provide such a substrate cleaning apparatus that can reduce the possibility of inverse contamination due to the cleaning member being induced into the substrate and can exhibit the cleaning ability for a long time.

According to the invention as defined in claim 8, since the substrate cleaning apparatus is provided with a hardness meter, a thin film hardness meter or a CCD for monitoring whether or not the coating layer of the porous polymeric material is present in the cleaning member, it becomes possible to provide such a substrate cleaning apparatus that allows to observe a condition of the coating layer of the cleaning member at any time, including the presence or absence of the coating layer and the condition of damage in the coating layer, thus making it possible to predict quickly when the cleaning member should be replaced.

According to the invention as defined in claim 9, since the substrate cleaning apparatus is further provided with a means for outputting a replacement signal when a pore distribution and/or hardness monitored on the cleaning member is shifted from a pore distribution and/or hardness of the coating layer of the porous polymeric material to those of the core portion, it becomes possible to provide such a substrate cleaning apparatus that allows to know the exact time when the cleaning member should be replaced.

According to the invention as defined in claim 10, since the substrate cleaning section of the substrate processing apparatus employs the substrate cleaning apparatus in accordance with any one of claims 7 to 9, it becomes possible to provide such a substrate processing apparatus that allows for the substrate having finished with a predetermined course of processing in the substrate processing section to be cleaned at any time with a high level of cleanness without any fear of inverse contamination being induced into the substrate.

### BRIEF DESCRIPTION OF THE DRAWINGS

FIG. 1 is a schematic view showing an exemplary configuration of an embodiment of a substrate cleaning apparatus using a cleaning member according to the present invention;

FIG. 2 is a schematic view showing an exemplary configuration of another embodiment of a substrate cleaning apparatus using a cleaning member according to the present invention;

FIG. 3 shows an exemplary configuration of an embodiment of a pen-type cleaning member according to the present invention;

FIG. 4 shows an exemplary configuration of another embodiment of a pen-type cleaning member according to the present invention;

FIG. 5 shows an exemplary configuration of a further embodiment of a pen-type cleaning member according to the present invention;

FIG. 6 shows an exemplary configuration of an embodiment of a roll-type cleaning member according to the present invention;

FIG. 7 shows another exemplary configuration of a roll-type cleaning member according to the present invention;

FIG. 8 shows another exemplary configuration of a roll-type cleaning member according to the present invention;

FIG. 9 is a diagram for illustrating a condition of contamination and contaminant to be discharged in a cleaning member of the prior art and in a cleaning member according to the present invention;

FIG. 10 is another diagram illustrating a condition of contamination and contaminant(s) to be discharged in a cleaning member of the prior art and in a cleaning member according to the present invention;

FIG. 11 is a schematic diagram showing an exemplary configuration of a cleaning member cleaning mechanism of a substrate cleaning apparatus according to the present invention;

FIG. 12 is a schematic diagram showing another exemplary configuration of a cleaning member cleaning mechanism of a substrate cleaning apparatus according to the present invention; and

FIG. 13 is a schematic diagram showing an exemplary configuration of a substrate processing apparatus according to the present invention.

### DESCRIPTION OF THE PREFERRED EMBODIMENTS

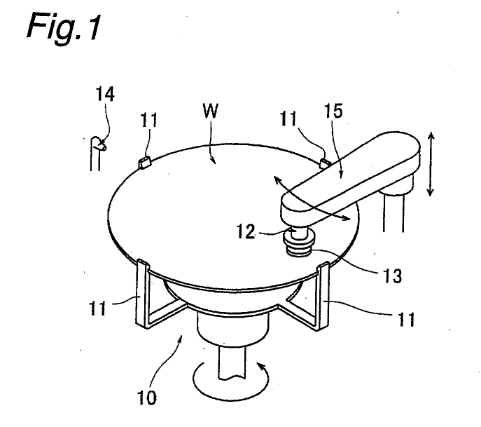

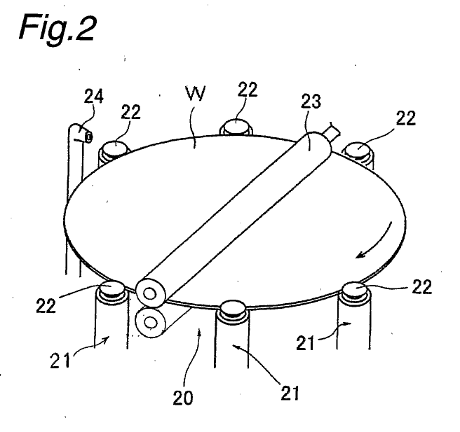

Preferred embodiments of the present invention will now be descried with reference to the attached drawings. FIGS. 1 and 2 are schematic drawings showing different exemplary configurations of a first and second embodiments of a substrate cleaning apparatus using a cleaning member according to the present invention, respectively, wherein FIG. 1 shows a configuration for a substrate cleaning apparatus, using a pen-type cleaning member and FIG. 2 shows a configuration for a substrate cleaning apparatus using a roll-type cleaning member.

The substrate cleaning apparatus shown in FIG. 1, comprises a substrate retaining and spinning mechanism 10 adapted to hold a substrate W in its periphery by a plurality (four in the drawing) of engaging pins 11 and to spin the substrate W along with the engaging pins 11, in which a circular disk-shaped cleaning member 13, which continues to spin while being held by a cleaning member retaining and spinning mechanism 12, and is brought into contact with the spinning substrate W. In this substrate cleaning apparatus, a top surface of the substrate can be cleaned with the aid of a relative motion between the substrate W and the cleaning member 13, while a cleaning liquid being supplied onto the surface of the rotating substrate W from a cleaning liquid supply nozzle 14. It is to be noted that the cleaning member retaining and spinning mechanism 12 is rotatably supported by a swing arm 15 and the cleaning member 13 is adapted simultaneously to rotate on its own axis and to move in a swinging manner along the left-right direction across the top surface of the substrate W.

The substrate cleaning apparatus shown in FIG. 2 comprises a substrate retaining and spinning mechanism 20 with a plurality (six in the drawing) of spindles 21 adapted to clamp a substrate W in its periphery by rotating rollers 22 located on top of the spindles 21 for spinning the substrate W, in which a pair of cylindrical cleaning members 23 is brought into contact with the top and the back surfaces of the spinning substrate W, respectively. In this substrate cleaning apparatus, the top and the back surfaces of the substrate W can be cleaned with the aid of a relative motion between the substrate W and the cleaning members 23 that are rotated by a cleaning member rotational driving mechanism (not shown), while cleaning liquid being supplied onto the top and the back surfaces of the substrate W from a cleaning liquid supply nozzle 24 (the illustration of the cleaning liquid supply nozzle for the back surface is herein omitted).

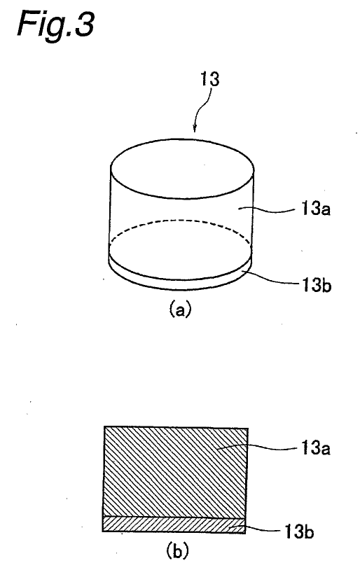

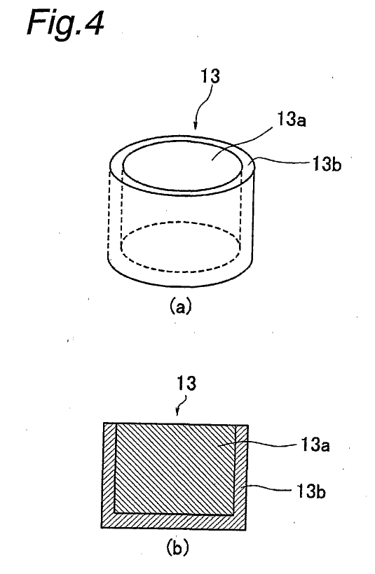

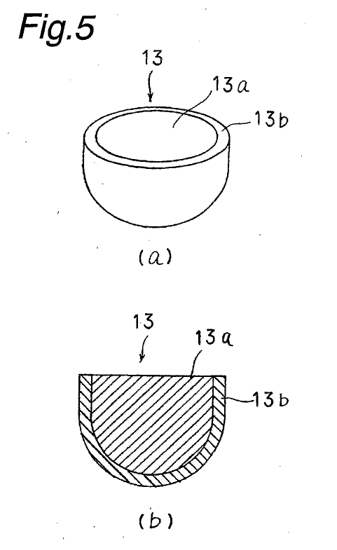

FIGS. 3 to 5 are illustrations of exemplary configurations of embodiments of the circular disk-shaped cleaning member (pen-type cleaning member) 13 as described above, respectively. A cleaning member 13 having the configuration shown in FIG. 3 comprises a circular disk-shaped (or cylindrical) core portion 13a and a coating layer 13b made of porous polymeric material, which is integrally formed with and over the lower end surface of the core portion 13a. It is to be noted that FIG. 3(a) shows an external view and FIG. 3(b) shows a sectional side view of the cleaning member 13 in this configuration. A cleaning member 13 having the configuration shown in FIG. 4 comprises a circular disk-shaped (or cylindrical) core portion 13a and a coating layer 13b made of porous polymeric material, which is integrally formed with the core portion 13a to define a lower end surface and a circumferential wall surrounding the core portion 13a. It is to be noted that FIG. 4(a) shows an external view and FIG. 4(b) shows a sectional side view of the cleaning member 13 in this configuration. A cleaning member 13 having the configuration shown in FIG. 5 comprises an approximately semi-spherical core portion 13a and a coating layer 13b made of porous polymeric material, which is integrally formed with and over the core portion 13a to define an exterior wall covering the core portion 13a. It is to be noted that FIG. 5(a) shows an external view and FIG. 5(b) shows a sectional side view of the cleaning member 13 in this configuration.

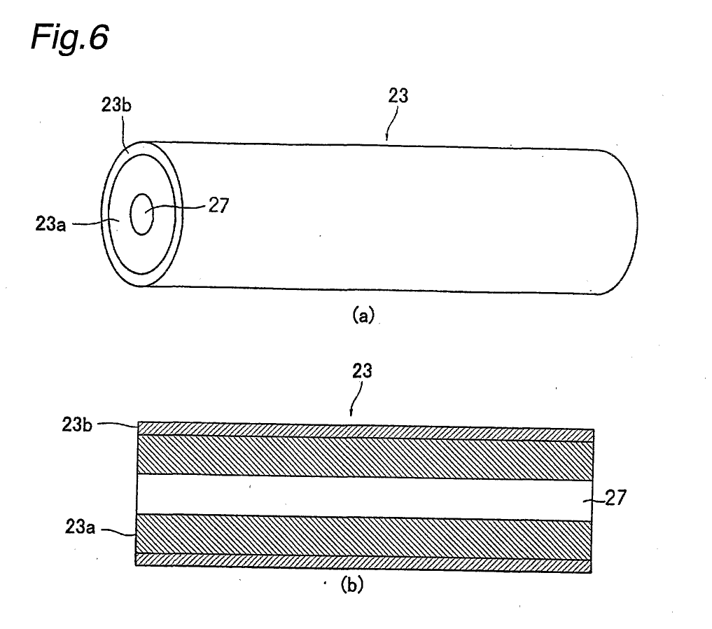

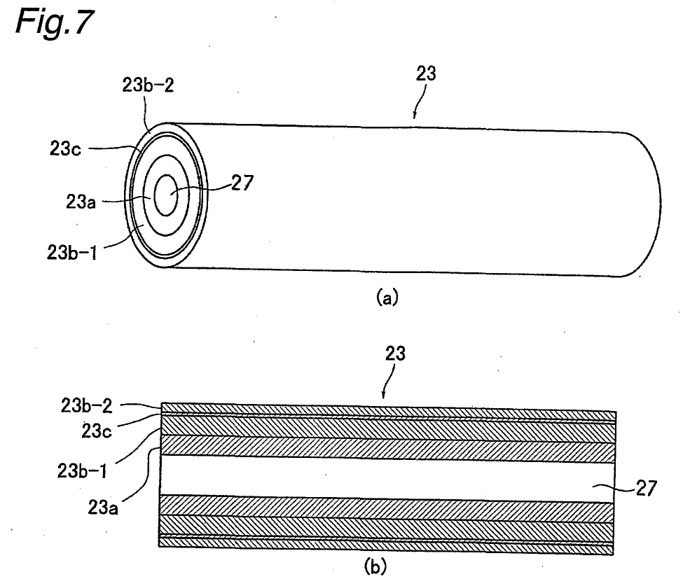

FIGS. 6 and 7 are illustrations of exemplary configurations of a roll-type cleaning member 23 as described above, respectively. A cleaning member 23 having the configuration shown in FIG. 6 comprises a cylindrical core portion 23a and a coating layer 23b made of porous polymeric material, which is integrally formed with and over a circumferential surface of the core portion 23a. A cleaning member 23 having the configuration shown in FIG. 7 comprises a cylindrical core portion 23a, a coating layer 23b-1 made of porous polymeric material over a circumferential surface of the core portion 23a, a waterproof layer 23c made of a waterproof material over a circumferential surface of the coating layer 23b-1 and another coating layer 23b-2 made of porous polymeric material over a circumferential surface of the waterproof layer 23c. Specifically, the cleaning member shown in FIG. 7 has employed the configuration including the waterproof layer 23c made of a waterproof material interposed between the coating layers 23b-1 and 23b-2, both made of porous polymeric materials and defining the circumferential layers with respect to the core portion 23a. The waterproof layer 23c and the coating layers 23b-1 and 23b-2 may be integrally formed. In FIGS. 6 and 7, reference numeral 27 designates a through hole through which a shaft (a revolving shaft member) is fittingly inserted.

As the friction between the substrate W and the cleaning member 13 or 23 could abrade the coating layer 13b or 23b in the top surface layer of the cleaning member 13 or 23, thus reducing the cleaning effect, it would be required to replace the cleaning member 13 or 23 with a new one, when a mass of the coating layer 13b or 23b in the top surface has been abraded by about 10 μm. For the cylindrical cleaning member 23 having a diameter around 300 mm, the top layer mass corresponding to 10 μm is substantially equal to 0.2% of a total volume of the cleaning member 23. The volume other than the top surface layer of the cleaning member 13 or 23 would not contribute directly to the stripping of the contaminants.

On the other hand, the greater the volume of the coating layer 13b or 23b made of porous polymeric material is, the higher the capacity of the coating layer 13b or 23b to hold the contaminants could be. The cleaning member 13 or 23 is only required to be flexible but is not necessarily made entirely of a water absorbing porous material. In this viewpoint, the cleaning member 13 or 23 according to the present invention intends, on one hand, to preserve the flexibility and the contaminant removing ability accomplished by the whole cleaning member and, on the other hand, to block the contaminants from entering into the cleaning member 13 or 23 and thus to reduce a degree of inverse contamination in the substrate, by advantageously employing the water absorbing porous polymeric material having a high flexibility for forming the coating layer 13b or 23b which is to be brought into direct contact with the substrate W and the resilient material having the waterproof property for forming the core portion 13a or 23a, as described above. Although the thinner coating layer 13b or 23b can provide a smaller volume allowable for the contaminant to be accumulated, the thickness of the top layer should be in a range of 10 μm to 15 mm, as derived from the solution to the flexibility that can be supplemented by including a sufficient amount of pores and by taking a range of pressure applied on the substrate into account.

The material used to form the core portion 13a or 23a may be any one selected from a group consisting of flexible cellular plastic foams; soft rubbers including fluoro rubber, silicon rubber, PHOSPHAZENE rubber and urethane rubber; and epoxy resins. Since those types of material have a waterproof property and resilience, they can favorably block contaminants from entering into the core portion 13a or 23a and still help preserve the flexibility in the whole unit of cleaning member 13 or 23.

The material used to form the coating layer 13b or 23b may employ any one of a polymeric material selected from a group consisting of PVA (polyvinyl alcohol) polymers, acrylic acid polymers, other addition polymers, acryl amide polymers, polyoxyethylene polymers, polyether polymers, condensation polymers, polyvinyl pyrrolidone, polystyrene aurfonic acid, urethane resins, and polyurethane resins. Since those types of material have flexibility and water absorbing property, they are less apt to damage the substrate W and instead have a higher ability to remove contaminants.

The core portion 13a or 23a made of one of the above listed materials having a waterproof property as well as resilience may be provided with the coating layer 13b or 23b made of one selected from the above listed materials over the top of the core portion 13a or 23a by using any one of thermal deposition, bonding using glue, pressure bonding, thermal compression and spray coating.

In the cleaning member 23 that has employed the configuration, as shown in FIG. 7, in which the circumferential surface of the core portion 23a made of the material having a waterproof property is covered with the coating layer 23b-1 made of the porous polymeric material having flexibility and high water absorbency, the circumferential surface of the coating layer 23b-1 is then covered with the waterproof layer 23c made of the material having a waterproof property, and further the circumferential surface of the waterproof layer 23c is covered with the coating layer 23b-2 made of the porous polymeric material, the waterproof layer 23c serves both to prevent any contaminant-contained liquid and/or contaminant particles from entering into the coating layer 23b-1 covering the circumferential surface of the core portion 23a and to prevent the contaminant from releasing out of the core portion 23a and the coating layer 23b-1 into the coating layer 23b-2 or the surface area to be brought into direct contact with the substrate W. The user of a cleaning apparatus can easily replace the existing cleaning member made of a porous material with the cleaning member according to the present invention without applying any particular work, since a portion contacting a substrate (outermost surface) and/or a mounting portion for the cleaning member (a contact region including the core portion to be brought into contact with a fixture, such as a shaft passing through the core portion, for fixing the cleaning member 23) are made of porous materials similar to the material of a prior art, and compatibility with the cleaning liquid, function and operation of the cleaning member according to the present invention are substantially the same as those of the cleaning member of a prior art. The contamination to the fixture can be blocked by the waterproof layer 23c, and would not affect the substrate W in nature.

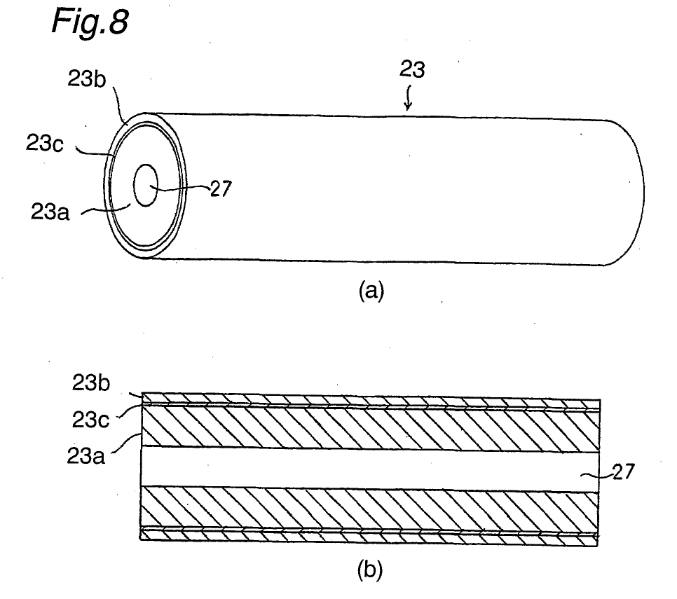

It is to be appreciated that although in the configuration as shown in FIG. 7, the waterproof layer 23c is disposed between the coating layer 23b-1 and the coating layer 23b-2, which are made of a porous polymeric material and disposed circumferentially with respect to the core portion 23a, alternatively the waterproof layer 23c may be disposed between the core portion 23a and the coating layer 23b made of the porous polymeric material as shown in FIG. 8, which still can provide substantially the same operational effect as that provided by the cleaning member 23 as shown in FIG. 7. Applying the waterproof treatment to both ends of the cleaning member 23 with the waterproof layer 23c having already arranged therein, as shown in FIGS. 7 and 8, can eliminate the requirement that the core portion 23a should be made of any waterproof material or that the waterproof property of the core portion 23a should be taken into consideration, thereby allowing for the material exclusively suitable for the performance of the core portion 23a to be selected and accordingly giving a broader selection range of the material usable to make the core portion 23a.

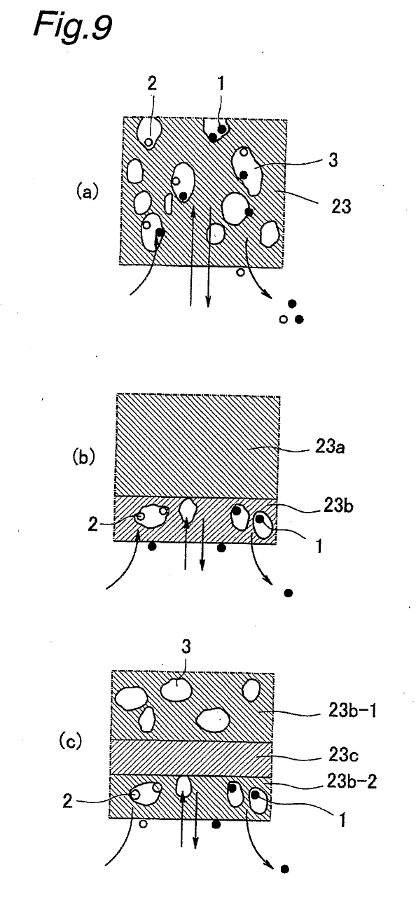

FIG. 9 conceptually illustrates the entering and discharging of the particles of contaminant with reference to a part of the cleaning member 13 or 23. In the illustration, a black spot 1 represents an entering particle of a contaminant and a white spot 2 represents an initially remaining particle of a contaminant, and reference numeral 3 represents a pore. For the cleaning member entirely made of porous polymeric material having the water absorbing property and flexibility as with the prior art cleaning member, it is more likely for a large quantity of contaminant-contained liquid and/or entering particles of contaminant 1 to be absorbed deep into the cleaning member 13 or 23 made of a porous polymeric material having the water absorbing property and flexibility, and also more possibly for the initially remaining particles of contaminant 2 to be discharged from the inside of the cleaning member, as shown in FIG. 9(a). For the cleaning member comprising the coating layer 13b made of a porous polymeric material covering the outer surface of the core portion 13, as shown in FIGS. 3 to 5, there is a smaller quantity of entering particles of contaminant 1 observed, because the contaminant-contained liquid and/or the particles of contaminant 1 is(are) only taken into the coating layer 23b (the region designated by 23b in the illustration), as shown in FIG. 9(b). In addition, since the quantity of the initially remaining particles of contaminant 2 is also small, the quantity of particles to be discharged is consequently small.

For the cleaning member comprising the coating layer 23b made of a porous polymeric material having the water absorbing property and flexibility covering the circumferential surface of the core portion 23a made of a waterproof material, as shown in FIG. 6, there is a smaller quantity of entering particles of contaminant 1 observed, because the contaminant-contained liquid and/or the particles of contaminant 1 is(are) only taken into the coating layer 23b, as shown in FIG. 9(b). In addition, since the quantity of the initially remaining particles of contaminant 2 is also small, the quantity of particles to be discharged is consequently small. Further, for the cleaning member comprising a waterproof layer 23c interposed between the coating layers 23b-1 and 23b-2 made of a porous polymeric material having a water absorbing property and flexibility, as shown in FIG. 7, there is a smaller quantity of entering particles of contaminant 1 observed, because the contaminant-contained liquid and/or the particles of contaminant 1 is(are) only taken into the coating layer 23b-2 disposed circumferentially in the exterior layer with respect to the waterproof layer 23c, as shown in FIG. 9(c). In addition, since the quantity of the initially remaining particles of contaminant 2 is also small, the quantity of particles to be discharged is consequently small.

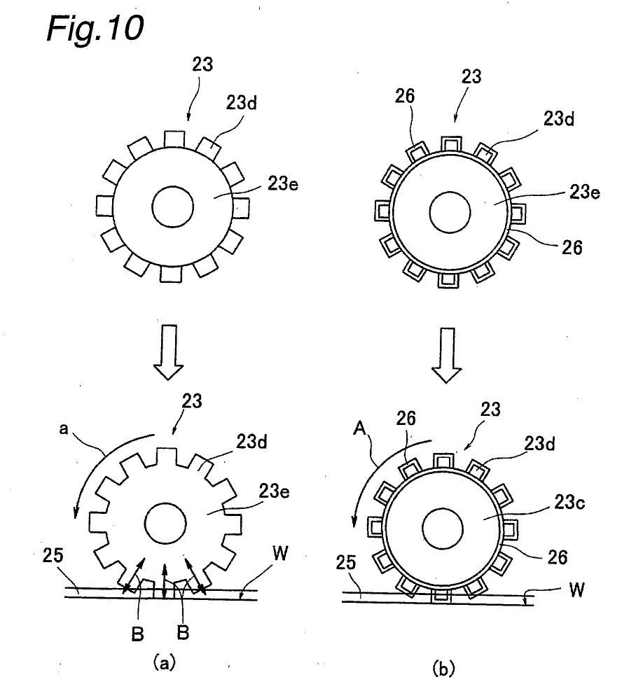

FIG. 10 illustrates a condition of contamination in the roll-type cleaning member comprising a plurality of protrusions formed in the circumferential surface of the cleaning member, wherein FIG. 10(a) represents the cleaning member 23 including protrusions 23d in the circumferential surface and a roll body 23e, which are entirely made of a porous polymeric material having a water absorbing property and the flexibility, and FIG. 10(b) represents the cleaning member 23 including the protrusions 23d and the roll body 23e, which are made of a material having a waterproof property, and additionally the coating layer 26 covering the exterior surfaces of the protrusions 23d and the roll body 23e, respectively, which is made of a porous polymeric material having a water absorbing property and the flexibility. In the foregoing embodiments, the plurality of protrusions are disposed on the outer surface of the roll body in a circumferentially spaced relation and are integrally formed with the roll body. Each of the protrusions may extend along the axis of the roll body over the entire length thereof or may be separated into a plurality of sections over the length of the roll body.

When the cleaning member 23 of each type of configuration as specified above is brought into contact with the substrate W and rotated in the direction as indicated by the arrow “a” while supplying the cleaning liquid 25 onto the top surface of the substrate W, specifically in the cleaning member 23 entirely made of a porous polymeric material having a water absorbing property and flexibility as shown in FIG. 10(a), the contaminated cleaning liquid and/or the particles of the contaminant penetrate through the protrusions 23d to be absorbed into the roll body 23e, as indicated by the arrow B, resulting in a large accumulation of the contaminated cleaning liquid and/or the particles of the contaminant inside the cleaning member 23. Consequently, the amount of the contaminated liquid and/or the particles of contaminants to be discharged from the cleaning member 23 would be large, meaning a higher probability for the substrate W to be contaminated inversely. In contrast, specifically in the cleaning member 23 comprising the coating layer 26 made of a porous polymeric material having a water absorbing property and the flexibility that defines exclusively the exterior surfaces of the protrusions 23d and the roll body 23e, respectively, the contaminated cleaning liquid and/or the particles of the contaminant would be only accumulated in the thin coating layer 26 but they would not penetrate the protrusions 23d or the roll body 23e, both made of a material having a waterproof property, resulting in an extremely small amount of accumulation of the contaminated cleaning liquid and/or the particles of contamination, and accordingly the amount of the contaminated liquid and/or the particles of the contaminant to be discharged from the cleaning member 23 would be extremely small, meaning a reduced probability for the substrate W to be contaminated inversely.

Thus, it becomes possible to maintain the cleaning member 13 or 23 always in a cleaned condition with no or, if any, an extremely small amount of the contaminant, by providing a substrate processing apparatus constructed such that the surface to be processed of the substrate W can be processed through a relative motion between the surface of the substrate W and a cleaning member configured as illustrated in FIGS. 3, 4, 5, 6, 7, 8 and 10(b) and brought into contact with the substrate, while a processing liquid being supplied onto the surface of the substrate W, and additionally by providing thus constructed substrate processing apparatus with a mechanism operable to remove the contaminant by bringing the substrate W into contact with the coating layer of the porous polymeric material of the cleaning member 13 or 23 so as to cause friction therebetween.

Further, if the cleaning member 13 of the cleaning apparatus as shown in FIG. 1 uses a cleaning member that has employed any one of the configurations as shown in FIGS. 3 to 5 and the cleaning apparatus is further provided with a micro-size hardness meter, a thin film hardness meter or a CCD for monitoring whether or not the coating layer 13b of the porous polymeric material is present in the cleaning member 13, it becomes possible for a user to realize the condition of the coating layer 13b in the cleaning member 13 and to replace the cleaning member 13 with a new one at an appropriate timing for changing. Similarly, if the cleaning member 23 of the cleaning apparatus as shown in FIG. 2 uses a cleaning member that has employed any one of the configurations as shown in FIGS. 6, 7, 8 and 10(b) and the cleaning apparatus is further provided with a micro-size hardness meter, a thin film hardness meter or a CCD for monitoring whether or not the coating layer 23b, 26 of the porous, polymeric material is present in the cleaning member 23, it becomes possible for a user to realize the condition of the coating layer 23b, 26 in the cleaning member 23 and to replace the cleaning member 23 with a new one at an appropriate timing for changing.

Further, if the substrate processing apparatus or the substrate cleaning apparatus, either of which is configured as described above, is adapted to output a replacement signal upon detection of the pore distribution or the hardness monitored on the cleaning member 13, 23 having shifted from the coating layer to the core portion, it becomes possible to let the user know the appropriate timing for replacing the cleaning member with a new one.

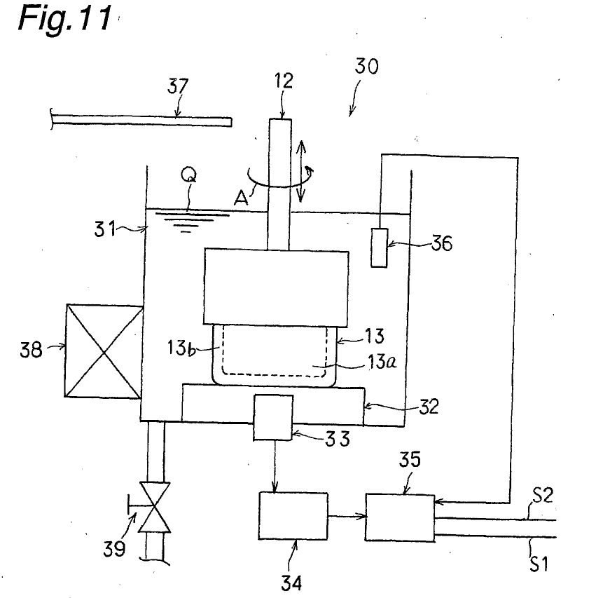

FIG. 11 is a schematic diagram showing an exemplary configuration for a cleaning member cleaning mechanism serving for monitoring the condition of the coating layer 13b in the cleaning member 13 having the configuration as shown in FIG. 4, while carrying out the cleaning process on the cleaning member 13. The cleaning member cleaning mechanism of this configuration is disposed in a predetermined location (stand-by position) outside of the substrate W in the substrate cleaning apparatus as shown in FIG. 1. The cleaning member cleaning mechanism 30 comprises a cleaning bath 31 including an observation wall 32 disposed in the bottom within the cleaning bath 31. The observation wall 32 is made of a transparent material (e.g., crystal) and includes a CCD 33 disposed in a central section thereof, and in operation, an output signal from the CCD 33 is received by an image processing apparatus 34 where the signal is processed and converted into an image-processing signal, which in turn, is output to a controller 35.

Further, a liquid property sensor 36 is disposed within the cleaning bath 31 for measuring a number of particles in a cleaning liquid “Q” and/or a concentration of a composition of a cleaning liquid “Q”, and an output signal from the liquid property sensor 36 is also adaptively output to the controller 35. The controller 35 is adapted to, in receipt of the image-processing signal from the image processing apparatus 34 and the output signal from the liquid property sensor 36, generate, for example, a cleaning liquid replacement signal “S1” or a cleaning member replacement signal “S2” and output the generated signal to a control panel (not shown).

The cleaning bath 31 contains the cleaning liquid Q that has been supplied from a cleaning liquid supply pipe 37, and the cleaning member 13 rotatably carried by a swing arm of FIG. 1 and held by the cleaning member retaining and spinning mechanism 12 which is dipped into the cleaning liquid Q from above and pressed against an upper surface of the observation wall 32, where the cleaning member 13 is rotated in the direction indicated by the arrow A so as to be cleaned. Since the coating layer 13b is thin, the particles once absorbed into the coating layer 13b can be discharged effectively in this cleaning process. During this cleaning process of the cleaning member 13, ultrasonic waves are emitted from an ultrasonic generator 38 to excite the cleaning liquid Q for enhancing the cleaning operation. The number of particles in the cleaning liquid Q, the concentration of a composition of the cleaning liquid Q and the like are measured and observed by the liquid property sensor 36, so that when a condition indicating that the cleaning liquid Q has to be changed is detected, a drain valve 39 is open to discharge the cleaning liquid in the cleaning bath 31, while a quantity of cleaning liquid Q is newly introduced through the cleaning liquid supply pipe 37 into the cleaning bath 31 after the drainage.

The CCD 33 observes the condition of the coating layer 13b of the cleaning member 13 through the transparent observation wall 32, and the output signal from the CCD33 is, output to the image processing apparatus 34, as described above, where the output signal is converted via the image processing operation into the image-processing signal, which is in turn taken into the controller 35. The controller 35 is capable of analyzing the image-processing signal so as to recognize the condition of the coating layer 13b made of a porous polymeric material in the cleaning member 13, and so the controller 35 can output a cleaning member replacement signal S2 to the control panel at an appropriate timing for replacement. This may help the user replace the cleaning member 13 with a new one in a timely manner. For example, the controller 35 may output the replacement signal S2 indicative of the need for replacing the cleaning member 13 with a new one immediately upon detection of the coating layer 13b having become worn out and extremely thin or a part of the core portion 13a having been exposed. It is to be noted that similarly in the cleaning members as shown in FIGS. 3 and 5, the condition of the cleaning and coating layer 13b of the cleaning member 13 can be monitored by using the cleaning member cleaning mechanism having the configuration as shown in FIG. 11, though the illustration is omitted.

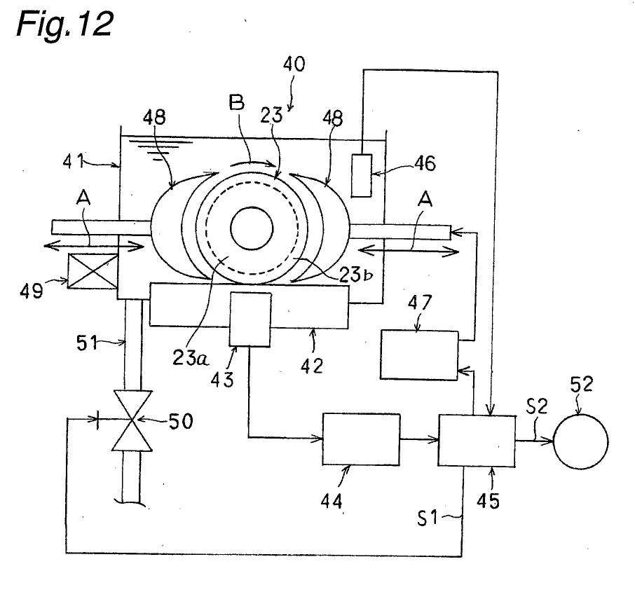

FIG. 12 is a schematic view showing an exemplary configuration of a cleaning member cleaning mechanism operable to monitor the condition of the coating layer 23b of the cleaning member 23 having the configuration as shown in FIG. 6, while cleaning the cleaning member 23. The cleaning member cleaning mechanism is disposed at a predetermined location (stand-by position) outside of the substrate W of the substrate cleaning apparatus as shown in FIG. 2. A cleaning member cleaning mechanism 40 comprises a cleaning bath 41 including an observation wall 42 disposed in the bottom within the cleaning bath 41. The observation wall 42 is made of a transparent material (e.g., crystal) and includes a CCD 43 disposed in a central section thereof, and in operation, an output signal from the CCD 43 is received by an image processing apparatus 44 where the signal is processed and converted into an image processing signal, which in turn is output to a controller 45.

Further, a liquid property sensor 46 is disposed within the cleaning bath 41 for measuring a number of particles in a cleaning liquid “Q” and/or a concentration of a composition of a cleaning liquid “Q”, and an output signal from the liquid property sensor 46 is also adaptively output to the controller 45. The controller 45 is adapted to, in receipt of the image-processing signal from the image processing apparatus 44 and the output signal from the liquid property sensor 46, generate, for example, a cleaning liquid replacement signal “S1” or a cleaning member replacement signal “S2” and output the generated signal to a cleaning liquid supply valve 50 and/or a cleaning member replacement signal generator 52.

The cleaning bath 41 is adapted to be supplied with a cleaning liquid Q through a cleaning liquid supply pipe 51 by opening a cleaning liquid supply valve 50 and to drain away the cleaning liquid Q by opening a drain valve, not shown. Further, a pair of cleaning jigs 48, 48 is disposed within the cleaning bath 41, which is operable to clamp or release the cleaning member 23 with a predetermined level of pressure by moving the cleaning member 23 placed on an upper surface of the observation wall 42 in the direction indicated by the arrows A, A. The pair of cleaning jigs 48, 48 is driven by a cleaning jig driver 47 so as to move in the direction indicated by the arrows A, A. In operation, the cleaning member 23 can be cleaned by being rotated in the direction indicated by the arrow B, as in the condition of the cleaning member 23 being pressed against the upper surface of the observation wall 42 with a predetermined level of pressure and clamped by the pair of cleaning jigs 48, 48. In this cleaning process, the particles that have been once absorbed into the coating layer 23b can be discharged effectively, because the coating layer 23b has been made thin. During this cleaning process of the cleaning member 23, ultrasonic waves are emitted from an ultrasonic generator 49 to excite the cleaning liquid Q for enhancing the cleaning effect. The number of particles in the cleaning liquid Q, the concentration of composition of the cleaning liquid Q and the like are measured and observed by the liquid property sensor 46, so that when a condition indicating that the cleaning liquid Q has to be changed is detected, a drain valve that is not illustrated is open to discharge the cleaning liquid Q in the cleaning bath 41, while a quantity of cleaning liquid Q is newly introduced through the cleaning liquid supply pipe 51 into the cleaning bath 41 by opening the cleaning liquid supply valve 50 after the drainage.

The CCD 43 observes the condition of the coating layer 23b of the cleaning member 23 through the transparent observation wall 42, and the output signal from the CCD 43 is output to the image processing apparatus 44, as described above, where the output signal is converted via the image processing operation into the image-processing signal, which is in turn taken into the controller 45. The controller 45 is capable of analyzing the image-processing signal so as to recognize the condition of the coating layer 23b made of a porous polymeric material in the cleaning member 23. For example, the controller 45 may output the replacement signal S2 indicative of the need for replacing the cleaning member 23 with a new one immediately upon detection of the coating layer 23b having become worn out and extremely thin or a part of the core portion 23a having been exposed. It is to be noted that similarly in the cleaning members as shown in FIGS. 7 and 10(b), the condition of the cleaning and coating layer 23b of the cleaning member 23 can be also monitored by using the cleaning member cleaning mechanism having the structure shown in FIG. 12, though the illustration is omitted.

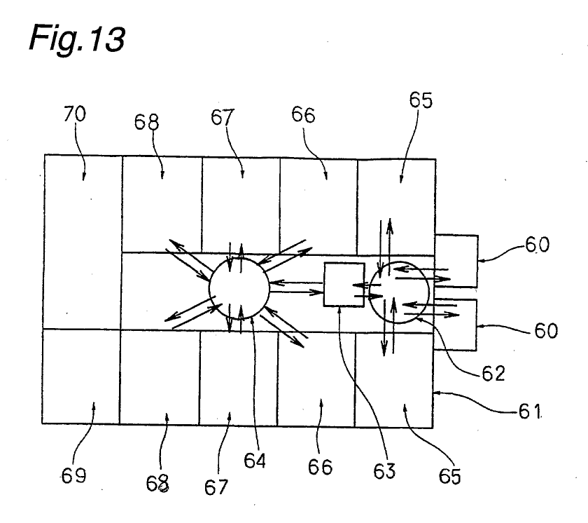

FIG. 13 is a schematic diagram showing an exemplary configuration in a plan view of a substrate processing apparatus (plating apparatus) according to the present invention. The substrate processing apparatus of the present invention comprises, for example, a frame arrangement 61 in a rectangular shape, which is adapted to be detachably loaded with a carrier box 60 comprising a SMIF box or the like containing a plurality of substrates such as wafers. There are a first substrate transfer robot 62, a temporary placement table 63 and a second substrate transfer robot 64, which are disposed in series in a central zone within the frame arrangement 61.

There are also arranged a pair of substrate cleaning and drying units 65, a pair of substrate cleaning units 66, a pair of plating pretreatment units 67 and a pair of plating pretreatment and plating units 68, each unit of the respective pairs being disposed in opposite sides within the frame arrangement 61, respectively. Further, a plating pretreatment liquid supply section 69 for supplying a plating pretreatment liquid to the plating pretreatment unit 67 and a plating liquid supply section 70 for supplying a plating liquid to the plating pretreatment and plating unit 68 are arranged in respective locations opposite to the carrier box 60. The substrate cleaning unit 66 uses the substrate cleaning apparatus having a configuration as shown in FIG. 1 or FIG. 2.

One piece of substrate W is taken out of the carrier box 60, transferred and placed onto a dry substrate retainer in the temporary placement table 63 by the first transfer robot 62. The substrate W retained by the dry substrate retainer (not shown) is transferred to the plating pretreatment unit 67 by the second substrate transfer robot 64, where the substrate W is subject to the plating pretreatment. The substrate W having finished with the plating pretreatment is, transferred by the second substrate transfer robot 64 to the plating pretreatment and plating unit 68, where the substrate W is subject to the plating pretreatment and plating process, and the substrate W having finished the plating process is further transferred by the second substrate transfer robot 64 to the substrate cleaning unit 66 having the configuration as shown in FIG. 1 or 2.

The substrate cleaning unit 66 is operable to clean the top and back surfaces of the substrate W so as to remove any particles and/or foreign materials adhering to the surfaces of the substrate W. The substrate W having the particles and/or foreign materials removed is transferred and placed onto a wet substrate retainer (now shown) in the temporary placement table 63 by the second substrate transfer robot 64.

The first substrate transfer robot 62 takes the substrate W from the wet substrate retainer in the temporary placement table 63 and transfers it to the substrate cleaning and drying unit 65, where the substrate W is subject to the cleaning process with a chemical and pure water and then spin-dried. The substrate W after its having been spin-dried is returned to the carrier box 60 by the first substrate transfer robot 62. Thus a series of processing of the substrate W would have been completed. Although the present invention has been described with reference to some embodiments, the present invention would not be limited to those specific embodiments but many variations may be made within a scope of the technical concept as defined in CLAIMS and described and illustrated in the SPECIFICATION and DRAWINGS.

1-10. (canceled)

11. A cleaning member for a substrate cleaning apparatus for cleaning a surface of a substrate to be cleaned by using a relative motion between said surface of the substrate and said cleaning member brought into contact with the surface of the substrate, while supplying a cleaning liquid onto said surface of the substrate, said cleaning member comprising:
a waterproof core portion.

12. A cleaning member in accordance with claim 11, wherein a surface of said core portion is coated with a porous polymeric material to define a coating layer.

13. A cleaning member in accordance with claim 11, in which said porous polymeric material is made of any one of a polymeric material selected from a group consisting of PVA (polyvinyl alcohol) polymers, acrylic acid polymers, other addition polymers, acryl amide polymers, polyoxyethylene polymers, polyether polymers, condensation polymers, polyvinyl pyrrolidone, polystyrene aurfonic acid, urethane resins, and polyurethane resins.

14. A cleaning member in accordance with claim 11, in which a thickness of said coating layer of said porous polymeric material is in a range of 5 μm to 15 mm.

15. A cleaning member in accordance with claim 11, in which said core portion is composed of any one of a waterproof material selected from a group consisting of: flexible cellular plastic foams; soft rubbers including fluoro rubber, silicon rubber, PHOSPHAZENE rubber, and urethane rubber; and epoxy resins.

16. A cleaning member in accordance with claim 11, in which a hardness of said coating layer of said porous polymeric material in a wet condition is equal to or lower than 100.

17. A cleaning member in accordance with claim 11, in which a waterproof layer made of a waterproof material is formed within said coating layer of said porous polymeric material or between said coating layer and said core portion.

18. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 11 for implementing said cleaning member.

19. A substrate cleaning apparatus in accordance with claim 18, comprising a hardness meter, a thin film hardness meter or a CCD for monitoring whether or not said coating layer of said porous polymeric material is present in said cleaning member.

20. A substrate cleaning apparatus in accordance with claim 19, further comprising a means for outputting a replacement signal when a pore distribution or hardness monitored on said cleaning member is shifted from a condition of said coating layer of said porous polymeric material to a condition of said core portion.

21. A substrate processing apparatus comprising a substrate processing section for carrying out a predetermined course of processing on a substrate and a substrate cleaning section for cleaning said substrate that has finished with said predetermined course of processing in said substrate processing section, said substrate processing apparatus employing a substrate cleaning apparatus in accordance with claim 18 for implementing said substrate cleaning section.

22. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 12 for implementing said cleaning member.

23. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 13 for implementing said cleaning member.

24. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 14 for implementing said cleaning member.

25. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 15 for implementing said cleaning member.

26. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 16 for implementing said cleaning member.

27. A substrate cleaning apparatus for cleaning a surface of a substrate to be cleaned by using a relative motion between said surface of the substrate and a cleaning member brought into contact with said surface of the substrate, while supplying a cleaning liquid onto said surface of the substrate, said substrate cleaning apparatus employing a cleaning member in accordance with claim 17 for implementing said cleaning member.

28. A substrate processing apparatus comprising a substrate processing section for carrying out a predetermined course of processing on a substrate and a substrate cleaning section for cleaning said substrate that has finished with said predetermined course of processing in said substrate processing section, said substrate processing apparatus employing a substrate cleaning apparatus in accordance with claim 19 for implementing said substrate cleaning section.

29. A substrate processing apparatus comprising a substrate processing section for carrying out a predetermined course of processing on a substrate and a substrate cleaning section for cleaning said substrate that has finished with said predetermined course of processing in said substrate processing section, said substrate processing apparatus employing a substrate cleaning apparatus in accordance with claim 20 for implementing said substrate cleaning section.
